(19) United States
(12) Patent Application Publication
(10) Pub. No.: US 2026/0122829 A1
(43) Pub. Date: Apr. 30, 2026

(54) SPIRAL WRAPPING TUBE WITH LOCKING FEATURES

(71) Applicant: Quanta Computer Inc., Taoyuan City (TW)

(72) Inventors: Yaw-Tzorng TSORNG, Taoyuan City (TW); Chen-Chien KUO, Taoyuan City (TW); Tang-Shun-Lee CHEN, Taoyuan City (TW); Chin-Yu LIN, Taoyuan City (TW)

(21) Appl. No.: 18/930,495

(22) Filed: Oct. 29, 2024

(51) Int. Cl. H05K 7/14

(52) U.S. Cl. CPC H05K 7/1491

(57) ABSTRACT

A computing system includes a structural support configured to receive one or more cables. The computing system further includes a wrapping tube configured for wrapping around a respective cable of the one or more cables. The wrapping tube includes a spiral body in the form of a strip of material that is disposed around a longitudinal axis. The spiral body has an interior surface and an exterior surface. The interior surface forms a wrapping space for receiving the respective cable of the one or more cables. A mounting tab extends outwardly from the exterior surface. The mounting tab attaches the wrapping tube to the structural support.

### FIELD OF THE INVENTION

The present invention relates generally to a spiral wrapping tube for bundling and supporting cables. More specifically, the present invention relates generally to a spiral wrapping tube with a locking feature for securing the spiral wrapping tube on a support structure such as a server rack.

### BACKGROUND OF THE INVENTION

Traditional spiral wrapping tubes are commonly used around cables and wires to bundle and support the cables and wires. However, traditional spiral wrapping tubes do not have a locking feature. Cable ties, tape, hook and loop fasteners, or the like are used to secure a traditional spiral wrapping tube to a support structure, for example, inside a server or on a rack. While these modes of attachment can be effective, they are often inconvenient and inefficiently time consuming. A need exists for a convenient and efficient system for securing a wrapping tube to a support structure. A need further exists for the system to be attachable to the support structure even if the support structure lacks predefined attachment points.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system includes a structural support configured to receive one or more cables. The computing system further includes a wrapping tube configured for wrapping around a respective cable of the one or more cables. The wrapping tube includes a spiral body in the form of a strip of material that is disposed around a longitudinal axis. The spiral body has an interior surface and an exterior surface. The interior surface forms a wrapping space for receiving the respective cable of the one or more cables. A mounting tab extends outwardly from the exterior surface. The mounting tab attaches the wrapping tube to the structural support.

According to certain aspects of the present disclosure, the structural support is a server rack.

According to certain aspects of the present disclosure, the mounting tab is connected to the spiral body via a tab spacer.

According to certain aspects of the present disclosure, the spiral body has a helical shape.

According to certain aspects of the present disclosure, the spiral body has multiple coils. Each coil of the multiple coils is separated by an intervening space from an adjacent coil.

According to certain aspects of the present disclosure, the wrapping tube includes multiple mounting tabs. At least one of multiple coils includes the mounting tab that extends outwardly from the exterior surface of the spiral body as noted above. Each coil has a respective mounting tab attached to it.

According to certain aspects of the present disclosure, each coil is attached to the respective mounting tab via a respective tab spacer.

According to certain aspects of the present disclosure, the mounting tab has a T-shape.

According to certain aspects of the present disclosure, the wrapping tube includes at least one additional mounting tab. The at least one additional mounting tab extends outwardly from the exterior surface in a different direction than the mounting tab.

According to certain aspects of the present disclosure, the computer system further includes a mounting clip. The mounting clip is configured for attachment with the mounting tab. The mounting clip is further configured to attach the mounting tab to the structural support.

According to certain aspects of the present disclosure, the mounting clip has an open slot in which the mounting tab is received.

According to certain aspects of the present disclosure, the mounting clip attaches to the structural support by one or a combination of several ways of attachment. The ways of attachment include: an extension of the mounting clip clipped over an edge of the structural support; the extension of the mounting clip clipped into an opening of the structural support; magnetic attraction to the structural support; an adhesive; a hook and loop attachment; or a screw.

According to certain aspects of the present disclosure, a computing system includes a structural support configured to receive one or more cables. The computing system further includes a wrapping tube configured for wrapping around a respective cable of the one or more cables. The wrapping tube includes a spiral body in the form of a strip of material that is disposed around a longitudinal axis. The spiral body has an interior surface and an exterior surface. The interior surface forms a wrapping space for receiving the respective cable of the one or more cables. A mounting tab extends outwardly from the exterior surface via a tab spacer. A mounting clip is attached to the structural support. The mounting clip is configured for attachment with the mounting tab.

According to certain aspects of the present disclosure, the wrapping tube includes at least one additional mounting tab. The at least one additional mounting tab extends outwardly from the exterior surface in a different direction than the mounting tab.

According to certain aspects of the present disclosure, the spiral body has a plurality of coils. Each coil of the plurality of coils is separated by an intervening space from an adjacent coil.

According to certain aspects of the present disclosure, the mounting clip attaches to the structural support by one or a combination of several ways of attachment. The ways of attachment include: an extension of the mounting clip clipped over an edge of the structural support; the extension of the mounting clip clipped into an opening of the structural support; magnetic attraction to the structural support; an adhesive; a hook and loop attachment; or a screw.

According to certain aspects of the present disclosure, a computing system includes a server rack configured to receive one or more cables. The computing system further includes a wrapping tube configured for wrapping around a respective cable of the one or more cables. The wrapping tube includes a spiral body in the form of a strip of material that is disposed around a longitudinal axis. The spiral body has an interior surface and an exterior surface. The interior surface forms a wrapping space for receiving the respective cable of the one or more cables. A plurality of mounting tabs extends outwardly from the exterior surface via a tab spacer. The plurality of mounting tabs is configured to attach the wrapping tube to the server rack.

According to certain aspects of the present disclosure, the plurality of mounting tabs is evenly distributed around the exterior surface of the spiral body.

According to certain aspects of the present disclosure, the computer system further includes a mounting clip configured for attachment with one of the plurality of mounting tabs, for attaching the wrapping tube to the server rack.

According to certain aspects of the present disclosure, the mounting clip attaches to the server rack by one or a combination of several ways of attachment. The ways of attachment include: an extension of the mounting clip clipped over an edge of the server rack; the extension of the mounting clip clipped into an opening of the server rack; magnetic attraction to the server rack; an adhesive; a hook and loop attachment; or a screw.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective schematic view showing a traditional wrapping tube.

FIG. 2 is a perspective schematic view of a traditional wrapping tube attached to a structural support via cable ties.

FIG. 3 is a perspective schematic view of an embodiment of a wrapping tube attached to a structural support, according to certain aspects of the present disclosure.

FIG. 4 is a perspective schematic view of an embodiment of a wrapping tube wrapped around a bundle of cables, according to certain aspects of the present disclosure.

FIG. 5A is a perspective schematic view of the wrapping tube of FIG. 4 without the bundle of cables, according to certain aspects of the present disclosure.

FIG. 5B is a schematic view of the wrapping tube of FIG. 5A viewed end on along the longitudinal axis, according to certain aspects of the present disclosure.

FIG. 6 is a schematic perspective view of the steps for attaching a wrapping tube to a structural support having mounting points, according to certain aspects of the present disclosure.

FIG. 7 is a schematic perspective view of a mounting clip, according to certain aspects of the present disclosure.

FIG. 8 is a schematic perspective view of a series of mounting clips attached to a structural support, according to certain aspects of the present disclosure.

FIG. 9 is a schematic perspective view of the steps for attaching a mounting clip to a mounting tab of a wrapping tube, according to certain aspects of the present disclosure.

FIG. 10 is a perspective schematic view of an embodiment of a wrapping tube wrapped around a bundle of cables and having several mounting points attached thereto, according to certain aspects of the present disclosure.

FIG. 11 is a perspective schematic view of an embodiment of a wrapping tube wrapped around a bundle of cables and attached to a structural support via mounting clips (not shown), according to certain aspects of the present disclosure.

FIG. 12 is a perspective schematic view of an embodiment of a wrapping tube wrapped around a bundle of cables and having a curvilinear longitudinal axis, according to certain aspects of the present disclosure.

FIG. 13 is a schematic view of a wrapping tube viewed end on along the longitudinal axis and having a spiral body that has a radius that varies along the longitudinal axis, according to certain aspects of the present disclosure.

### DETAILED DESCRIPTION

The current invention is a computing system that includes a structural support and a wrapping tube for wrapping cables and wires. The wrapping tube has a spiral body and at least one mounting tab that mounts the wrapping tube to the structural support. The mounting tab can mount directly to a mounting point on the structural support, or the mounting tab can mount to the structural support via an intermediate mounting clip that attaches to the structural support.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

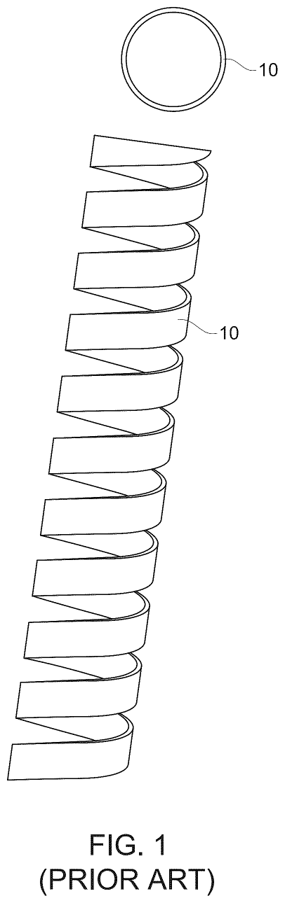

Referring to FIG. 1, an exemplary traditional spiral wrapping tube 10 does not have locking features. Because of this traditional structure, cable ties, tape, hook and loop fasteners, or the like are used to secure traditional spiral wrapping tubes 10 inside a server rack or to a cabinet or other structural support.

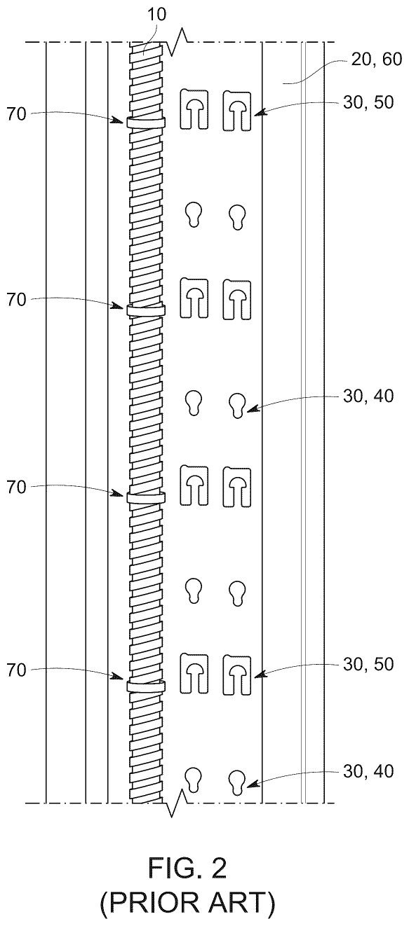

Referring to FIG. 2, which shows prior art, structural supports 20 often have a series of mounting points 30 arranged for attachment of traditional spiral wrapping tubes 10 or other components. For example without limitation, the series of mounting points 30 can each have an elongate two-sized slot 40 or a slot 50 with a central barb. FIG. 2 illustrates a traditional spiral wrapping tube 10 attached to the structural support 20, for example a server rack 60, by a plurality of cable ties 70. In this traditional arrangement, the cable ties 70 wrap around the central barbs of the respective slots 50.

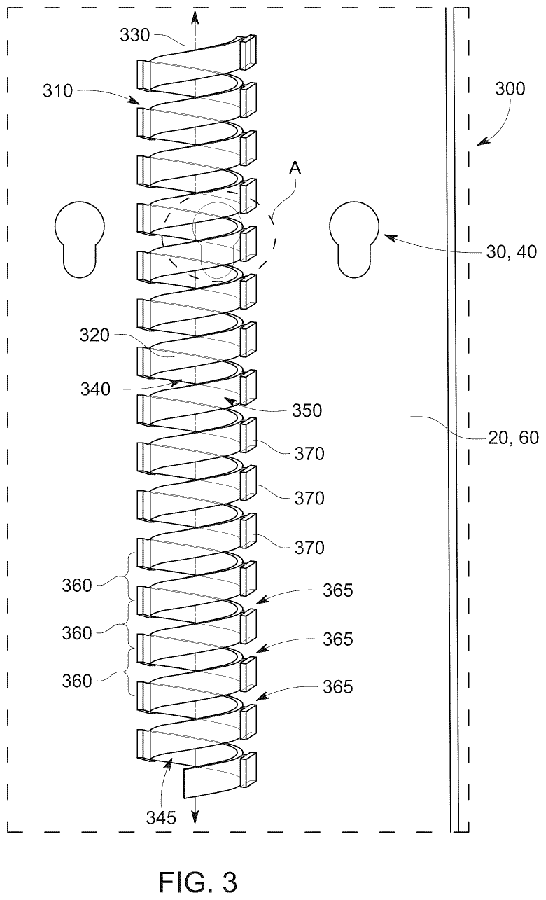

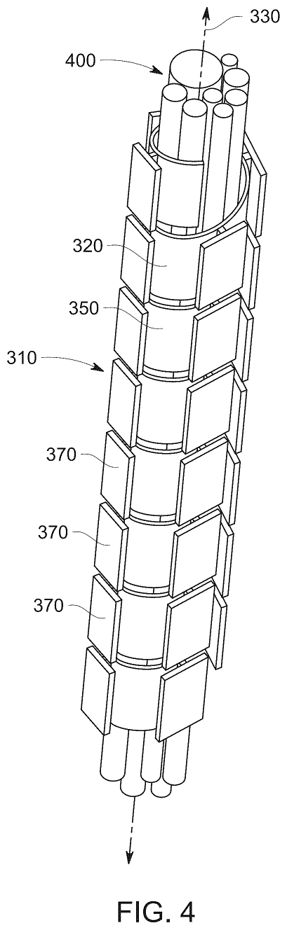

Referring to FIGS. 3 and 4, a wrapping tube 310 of a computing system 300 is shown in two exemplary contexts. In FIG. 3 the wrapping tube 310 is shown attached to a structural support 20 without any cables 400 to show the internal structure of the wrapping tube 310. In FIG. 4 the wrapping tube 310 is shown unattached from a structural support 20 but wrapped around the cables 400.

Referring to FIG. 3, an exemplary computing system 300 includes a structural support 20, for example, a server rack 60, configured to receive one or more cables 400 (see FIG. 4). The computing system 300 further includes a wrapping tube 310 configured for wrapping around a respective cable 400 of the one or more cables 400. The wrapping tube 310 includes a spiral body 320 in the form of a strip of material that is disposed around a longitudinal axis 330. The spiral body 320 has an interior surface 340 and an exterior surface 350. The interior surface 340 forms a wrapping space 345 for receiving the respective cable 400 of the one or more cables 400. The spiral body 320 has a plurality of coils 360. Each coil 360 of the plurality of coils 360 is separated from an adjacent coil 360 by an intervening space 365. In an embodiment, the spiral body 320 has a helical shape. In other embodiments, the spiral body 320 can be comprised of a combination of spiral coils 360 that are connected by longitudinally extending connectors (not shown).

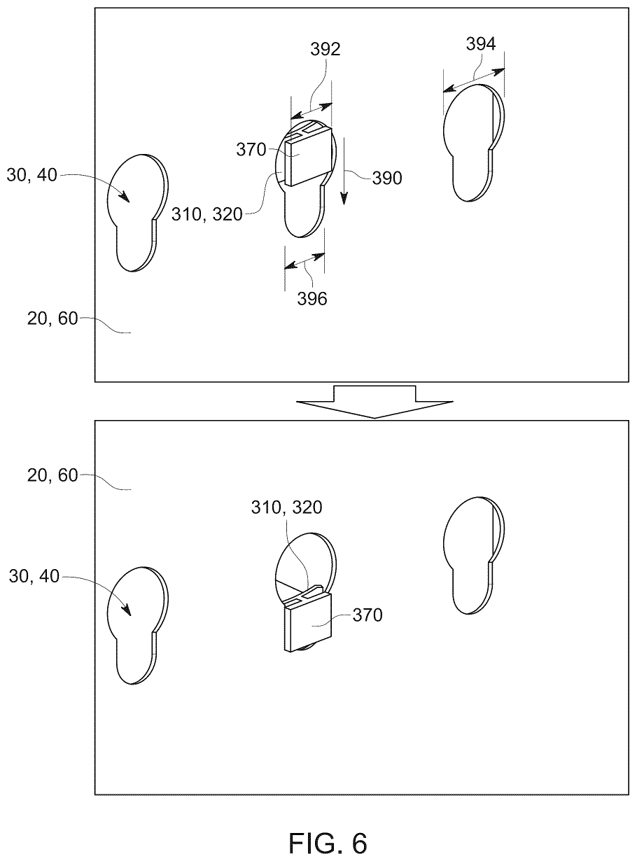

At least one mounting tab 370 extends outwardly from the exterior surface 350. The at least one mounting tab 370 attaches the wrapping tube 310 to the structural support 20. As indicated by the circled region labeled A in FIG. 3, the mounting tab 370 attaches into a mounting point 30. This attachment is further described in regard to FIG. 6 below. Each coil 360 includes at least one mounting tab 370 extending from the exterior surface 350.

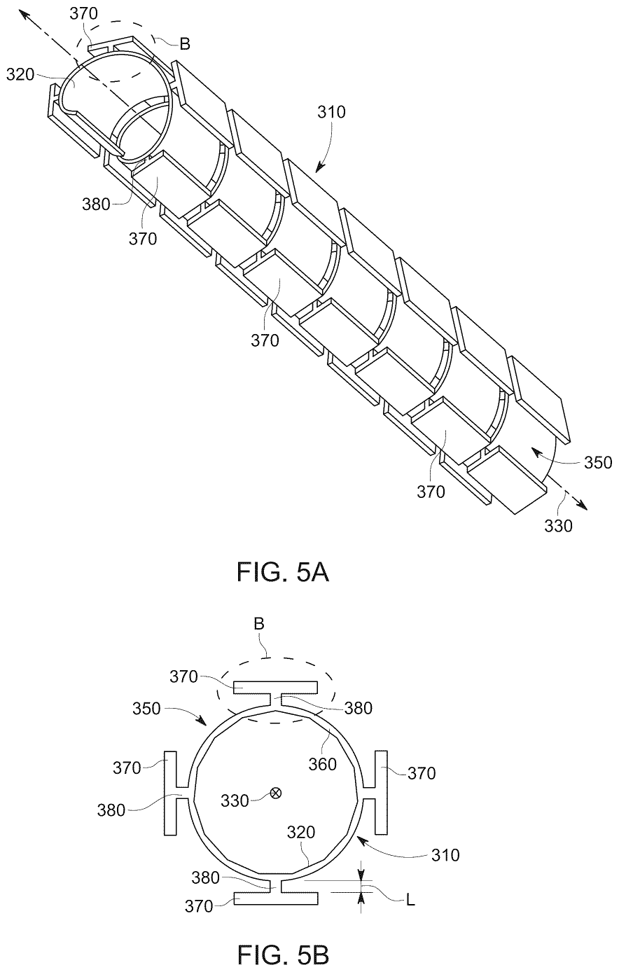

Referring to FIGS. 5A and 5B, in an embodiment, the at least one mounting tab 370 is connected to the spiral body 320 via a tab spacer 380. Attachment of the mounting tab 370 to the spiral body 320 via the tab spacer 380 is shown in the circled portions of FIGS. 5A and 5B labeled B. The wrapping tube 310 can have at least one additional mounting tab 370 beyond the at least one mounting tab 370, where the at least one additional mounting tab 370 extends outwardly from the exterior surface 350 in a different direction than the at least one mounting tab 370. In an embodiment, the wrapping tube 310 includes a plurality of mounting tabs 370. Each mounting tab 370 extends outwardly from the exterior surface 350 via a tab spacer 380. Each mounting tab 370 is configured to attach the wrapping tube 310 to a structural support 20 such as a server rack 60. For example, the plurality of mounting tabs 370 can be evenly distributed around the spiral body 320 such that the plurality of mounting tabs are staggered longitudinally along the exterior surface 350.

FIG. 5B shows the wrapping tube 310 viewed along the longitudinal axis 330. In this view, an entire coil 360 can be seen extending around the longitudinal axis 330. The coil 360 has mounting tabs 370 extending therefrom and, for example, distributed around the coil 360. Each mounting tab 370 is attached to the coil 360 via a respective tab spacer 380. The at least one mounting tab 370 has a T-shape when viewed along the longitudinal axis 330. Each of the mounting tabs 370 is illustrated in FIGS. 3-5B as rectangular; however, in other embodiments, the mounting tabs 370 can be round or elliptical or any polygonal shape, as desired or as required to work with mounting points 30 (FIG. 3) of a structural support 20 (FIG. 3).

The tab spacer 380 has a length L that separates the mounting tab 370 from the exterior surface 350 of the spiral body 320. The length L can be predetermined based on a thickness of the structural support 20 (FIG. 3), to which the wrapping tube 310 is intended to attach. The length L can be tailored to snugly or loosely attach the wrapping tube 310 to the structural support 20 as desired.

Referring to FIG. 6, an exemplary wrapping tube 310 has one or more mounting tabs 370. The wrapping tube 310 attaches to a structural support 20, for example a server rack 60, that has elongate two-sized slots 40 as mounting points 30. The mounting tab 370 has a width 392 that is smaller than a width 394 of the larger side of the two-sized slot 40, but larger than the width 396 of the smaller side of the two-sized slot 40. The wrapping tube 310 attaches to the structural support in two steps. In a first step, as shown in the top half of FIG. 6, the wrapping tube 310 is positioned such that a mounting tab 370 extends through the larger side of a two-sized slot 40. In a second step, the wrapping tube 310 is moved so that the mounting tab 370 is moved toward the smaller side of the two-sized slot 40, as indicated by the arrow 390. The mounting tab 370 is moved until it is positioned in the smaller side of the two-sized slot 40, as shown in the bottom half of FIG. 6. The width 392 of the mounting tab 370 being larger than the width 396 of the smaller side of the two-sized slot 40 secures the mounting tab 370 in the smaller side of the two-sized slot 40.

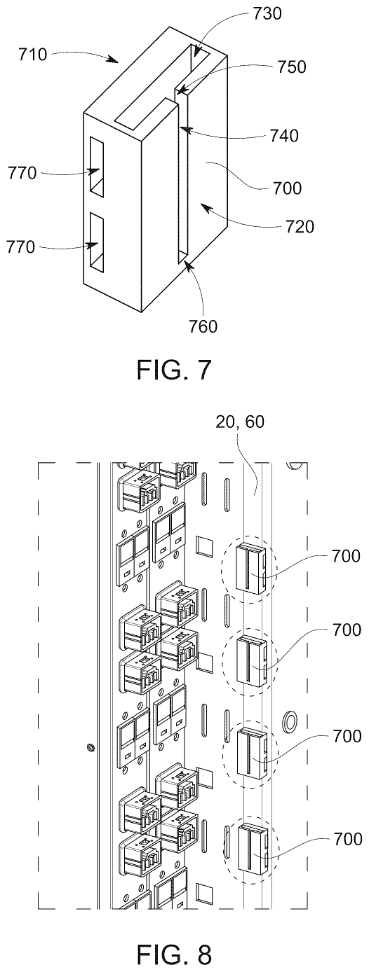

Referring now to FIGS. 7 and 8, some structural supports 20 (FIG. 3) or server racks 60 (FIG. 3) lack mounting points 30 (FIG. 3), into which the mounting tabs 370 (FIG. 3) can engage to support the wrapping tube 310 (FIG. 3). In an embodiment, one or more mounting clips 700 can be provided to attach the wrapping tube 310 to structural supports 20 that lack mounting points 30. Each mounting clip 700 is configured for attachment with a mounting tab 370 for attaching the mounting tab 370, and thereby also the wrapping tube 310, to the structural support 20.

Referring to FIG. 7, each mounting clip 700 includes a support facing side 710 and a tube facing side 720. In an embodiment, each mounting clip 700 includes an edge slot 730 disposed into the mounting clip 700 between the support facing side 710 and the tube facing side 720. Each mounting clip 700 further includes a tab slot 740 disposed through the tube facing side 720. The tab slot 740 has a depth that extends from the edge slot 730 to the tube facing side 720. The tab slot 740 has an open end 750 and an opposite closed end 760. The edge slot 730 is sized to accommodate the mounting tab 370 (FIG. 5B), and the tab slot 740 is sized to accommodate the tab spacer 380 (FIG. 5B).

In an embodiment, each mounting clip 700 further includes at least one mounting slot 770 that extends entirely through the mounting clip 700 and is parallel to the support facing side 710. Each mounting clip 700 can be attached to the structural support 20 (FIG. 3), for example a server rack 60 (FIG. 3), in any one or a combination of several ways. For example without limitation, the ways of attachment include: an extension of the mounting clip 700 clipped over an edge of the structural support 20; the extension of the mounting clip 700 clipped into an opening of the structural support 20; magnetic attraction to the structural support 20; an adhesive backing on the support facing side 710; hook and loop fastening strips; a screw or bolt; or any combination thereof. The mounting slot 770 also allows for attachment of the mounting clip 700 to a structural support 20 by a strip of material threaded through the slot. For example, tape or a cable tie 70 (FIG. 2) can be threaded through the slot 770 and be wrapped around a central barb of a slot 50 (FIG. 2).

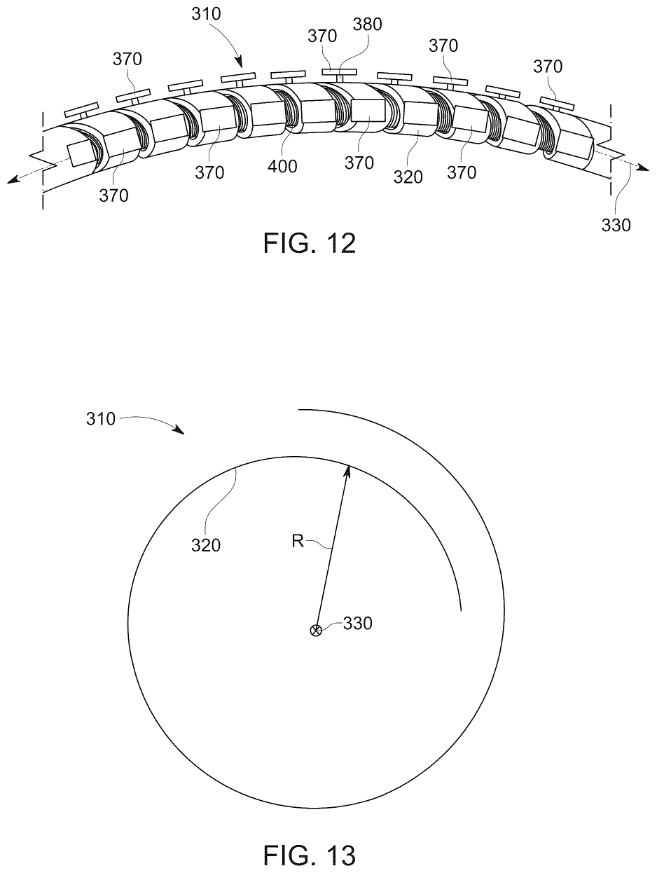

FIG. 8 illustrates a structural support 20 that lacks mounting points 30 (FIG. 6) suitable for attaching the mounting tabs 370 (FIG. 6). A series of mounting clips 700 is shown attached to the structural support 20. The mounting clips 700 thus attached to the structural support 20 are configured, for example, to support the mounting tabs 370 of a wrapping tube 310 (FIG. 6). The mounting tabs 370 are shown arranged linearly in a vertical orientation relative to the structural support 20. However, in other embodiments, the mounting tabs 370 can be arranged horizontally or diagonally relative to the structural support 20. The mounting tabs 370 can also have a curvilinear arrangement to accommodate a wrapping tube 310 having a curvilinear longitudinal axis 330, as shown in FIG. 12.

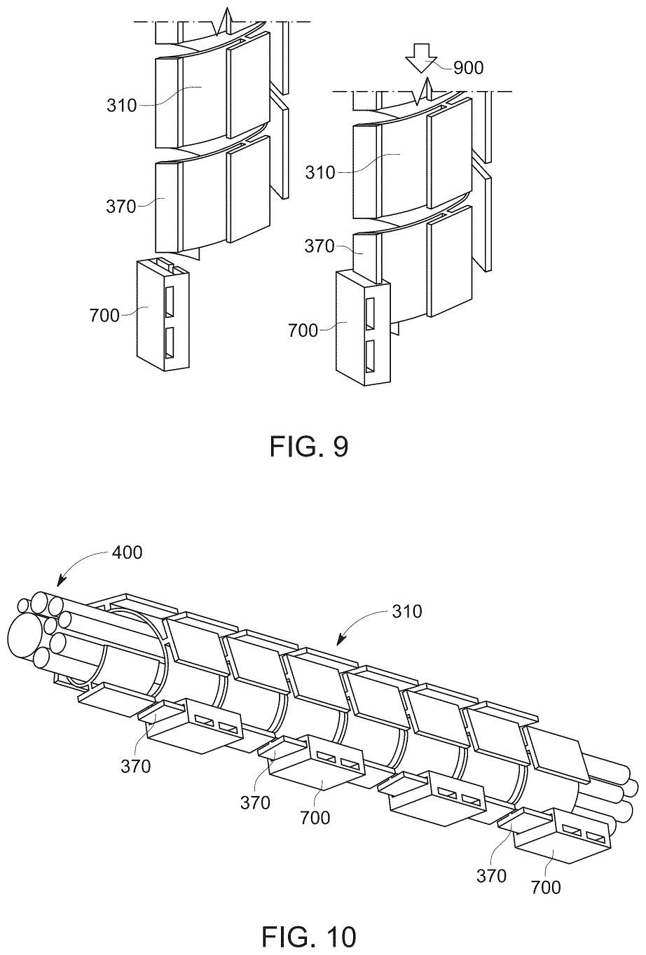

Referring to FIG. 9, alternatively, the mounting clips 700 can be attached to the wrapping tube 310 first, and then subsequently attached to the structural support 20 (FIG. 8). A mounting tab 370 of a wrapping tube 310 is positioned for insertion into a mounting clip 700, as shown on the left side of FIG. 9. As indicated by the arrow 900, the wrapping tube 310 is moved toward the mounting clip 700 to engage the mounting tab 370 with the mounting clip 700, as shown on the right side of FIG. 9.

FIG. 10 illustrates a wrapping tube 310 having a number of mounting clips 700 engaged over respective mounting tabs 370. The wrapping tube 310 in FIG. 10 is shown to be wrapped around one or more cables 400. The wrapping tube 310 with the mounting clips 700 attached can be attached via the mounting clips 700 to the structural support 20. Alternatively, as shown in FIG. 8, the mounting clips 700 can first be attached to the structural support 20 in an arrangement configured to accommodate attachment of the mounting tabs 370.

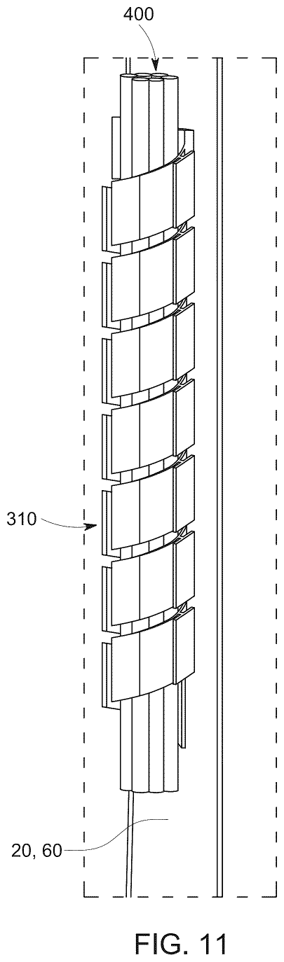

FIG. 11 illustrates the wrapping tube 310 wrapped around one or more cables 400 and attached to a structural support 20, for example a server rack 60, via one or more of the mounting clips 700 (FIG. 7), which are actually not visible in FIG. 11. The wrapping tube 310 is shown arranged linearly in a vertical orientation relative to the structural support 20. However, in other embodiments, the wrapping tube 310 can be attached horizontally or diagonally relative to the structural support 20.

Referring to FIG. 12, in an embodiment, the longitudinal axis 330 of the wrapping tube 310 is curvilinear. The wrapping tube 310 is shown wrapped around one or more cables 400. A curvilinear wrapping tube 310 can follow a curving path of the one or more cables 400 through the structural support 20. The curvilinear wrapping tube 310 can also bend around components or conform to internal surfaces of a structural support 20 (FIG. 3). In an embodiment, the wrapping tube 310 is linear but is longitudinally flexible allowing it to be bent as desired around the longitudinal axis 330.

Referring to FIG. 13, a wrapping tube 310 is schematically illustrated end on along the longitudinal axis 330 without the mounting tabs 370 (FIG. 12) for clarity. In this embodiment, a radius R of the spiral body 320 of the wrapping tube 310 varies along the longitudinal axis 330 such that the spiral body 320 spirals closer to or further away from the longitudinal axis 330 as illustrated. A variable radius R can be useful, for example, for the bundling of more or less cables 400 (FIG. 12) that may come together or separate along their routing path.

Referring back to FIG. 3, the wrapping tube 310, having either a linear or curvilinear longitudinal axis 330, can be attached to a structural support 20 having a series of two-sized slots 40 in any orientation of attachment that allows the mounting tabs 370 to align with the two-sized slots 40. Similarly, referring back to FIG. 11, the wrapping tube 310, having either a linear or curvilinear longitudinal axis 330, can be attached to a structural support 20 lacking mounting points 30 (FIG. 3) via engagement with mounting clips 700 (FIG. 7) attached to the structural support 20 in any orientation of attachment that allows the mounting tabs 370 to align with the mounting clips 700.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A computing system comprising:
a structural support configured to receive one or more cables; and
a wrapping tube configured for wrapping around a respective cable of the one or more cables, the wrapping tube including
a spiral body in the form of a strip of material that is disposed around a longitudinal axis, the spiral body having an interior surface and an exterior surface, the interior surface forming a wrapping space for receiving the respective cable of the one or more cables, and
a mounting tab extending outwardly from the exterior surface, the mounting tab attaching the wrapping tube to the structural support.

2. The computing system of claim 1, wherein the structural support is a server rack.

3. The computing system of claim 1, wherein the mounting tab is connected to the spiral body via a tab spacer.

4. The computing system of claim 1, wherein the spiral body has a helical shape.

5. The computing system of claim 1, wherein the spiral body has a plurality of coils, each coil of the plurality of coils being separated by an intervening space from an adjacent coil.

6. The computing system of claim 5, wherein the wrapping tube includes a plurality of mounting tabs, at least one of the plurality of coils including the mounting tab, each coil having attached thereto a respective mounting tab of the plurality of mounting tabs.

7. The computing system of claim 6, wherein each coil is attached to the respective mounting tab via a respective tab spacer.

8. The computing system of claim 1, wherein the mounting tab has a T-shape.

9. The computing system of claim 1, wherein the wrapping tube includes at least one additional mounting tab, the at least one additional mounting tab extending outwardly from the exterior surface in a different direction than the mounting tab.

10. The computing system of claim 1, further comprising a mounting clip configured for attachment with the mounting tab for attaching the mounting tab to the structural support.

11. The computing system of claim 10, wherein the mounting clip has an open slot in which the mounting tab is received.

12. The computing system of claim 10, wherein the mounting clip attaches to the structural support by an extension of the mounting clip clipped over an edge of the structural support, the extension of the mounting clip clipped into an opening of the structural support, magnetic attraction to the structural support, an adhesive, a hook and loop attachment, a screw, or any combination thereof.

13. A computing system, comprising:
a structural support configured to receive one or more cables;
a wrapping tube configured for wrapping around a respective cable of the one or more cables, the wrapping tube including
a spiral body in the form of a strip of material that is disposed around a longitudinal axis, the spiral body having an interior surface and an exterior surface, the interior surface forming a wrapping space for receiving a respective cable of the one or more cables,
a mounting tab extending outwardly from the exterior surface via a tab spacer, and
a mounting clip attached to the structural support, the mounting clip configured for attachment with the mounting tab.

14. The computing system of claim 13, wherein the wrapping tube includes at least one additional mounting tab, the at least one additional mounting tab extending outwardly from the exterior surface in a different direction than the mounting tab.

15. The computing system of claim 13, wherein the spiral body has a plurality of coils, each coil of the plurality of coils being separated by an intervening space from an adjacent coil.

16. The computing system of claim 13, wherein the mounting clip attaches to the structural support by an extension of the mounting clip clipped over an edge of the structural support, the extension of the mounting clip clipped into an opening of the structural support, magnetic attraction to the structural support, an adhesive, a hook and loop attachment, a screw, or any combination thereof.

17. A computing system comprising:
a server rack configured to receive one or more cables; and
a wrapping tube configured for wrapping around a respective cable of the one or more cables, the wrapping tube including
a spiral body in the form of a strip of material that is disposed around a longitudinal axis, the spiral body having an interior surface and an exterior surface, the interior surface forming a wrapping space for receiving the respective cable of the one or more cables, and
a plurality of mounting tabs each mounting tab extending outwardly from the exterior surface via a tab spacer and configured to attach the wrapping tube to the server rack.

18. The computing system of claim 17, wherein the plurality of mounting tabs is evenly distributed around the exterior surface of the spiral body.

19. The computing system of claim 17, further comprising a mounting clip configured for attachment with one of the plurality of mounting tabs, for attaching the wrapping tube to the server rack.

20. The computing system of claim 19, wherein the mounting clip attaches to the server rack by an extension of the mounting clip clipped over an edge of the server rack, the extension of the mounting clip clipped into an opening of the server rack, magnetic attraction to the server rack, an adhesive, a hook and loop attachment, a screw, or any combination thereof.
